(19) United States
(12) Patent Application Publication
(10) Pub. No.: US 2010/0051335 A1
(43) Pub. Date: Mar. 4, 2010

(54) Conducting Layer Jump Connection Structure

(75) Inventors: Chien-Li Chen, Hsin-Chu (TW); Shun-Fa Feng, Hsin-Chu (TW); Yan-Lin Yeh, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU Optronics Corporation, Hsin-Chu (TW)

(21) Appl. No.: 12/550,758

(22) Filed: Aug. 31, 2009

(30) Foreign Application Priority Data
Sep. 1, 2008 (TW) 97133483

(51) Int. Cl. H05K 1/11; H05K 1/09

(52) U.S. Cl. 174/257; 174/262

(57) ABSTRACT

A conducting layer jump connection structure used in a circuit device includes a substrate, a first conducting layer, a first insulating layer, a second conducting layer, a second insulating layer, a jump connection layer, a first via, and plural second vias. The first conducting layer covers the substrate. The first insulating layer covers the first conducting layer. The second conducting layer partially covers the first insulating layer. The second insulating layer covers the second conducting layer and the first insulating layer exposed by the second conducting layer. The jump connection layer covers the second insulating layer. The first via is formed on the first conducting layer and between two opposite second conducting portions of the second conducting layer. The first via penetrates through both the second insulating layer and the first insulating layer. The second vias are formed on the second conducting layer and penetrate through the second insulating layer. The first conducting layer and the second conducting layer are connected to the jump connection layer through the first via and the second vias, respectively.

### BACKGROUND OF THE INVENTION

1. Field of the Invention

This invention generally relates to a conducting layer jump connection structure. More particularly, this invention relates to a conducting layer jump connection structure used in a circuit device.

2. Description of the Prior Art

Liquid crystal displays are widely used in many electronic devices including computers, televisions, and mobile phones. As shown in FIG. 1A, signals of a circuit device of a conventional liquid crystal display 99 are transmitted through circuits. In the conventional liquid crystal display 99, signals outside the display area 99a can be transmitted through the first metal layer 10. However, for preventing interferences between the circuits, some signals can be directed into the display area 99a through the electrical connection structure 90 and then transmitted through the second metal layer 20. Therefore, the durability and the conduction stability of the electrical connection structure 90 is one of the most important factors influence the performance of the liquid crystal display.

As Shown in FIG. 1B, the electrical connection structure 90 used in the conventional circuitry includes a substrate 700 and stacked layers including, from bottom to top, a first metal layer 10, a first insulating layer 30, a second metal layer 20, a second insulating layer 40, and an indium tin oxide (ITO) layer 80. The second metal layer 20 partially covers the first insulating layer 30.

First vias 50 and second vias 60 are formed on the first metal layer 10 and the second metal layer 20, respectively. The first vias 50 penetrate through both the second insulating layer 40 and the first insulating layer 30. The second vias 60 penetrate through the second insulating layer 40. The first vias 50 and the second vias 60 are filled with indium tin oxide. Since indium tin oxide is conductive, the first metal layer 10 and the second metal layer 20 can connected to the ITO layer 80 by means of the indium tin oxide filled in the first via 50 and the second vias 60, respectively.

Because indium tin oxide has low conductivity and high resistivity compared to the metal materials of the first metal layer 10 and the second metal layer 20, when electric charges flow from the first metal layer 10 to the second metal layer 20, the electric charges tend to flow in the first metal layer 10 to the first via 50′ which is closer to the second metal layer 20 and then to the second metal layer 20 through the indium tin oxide in the first via 50′, the ITO layer 80, and the indium tin oxide in the second via 60′ which is closer to the first metal layer 10. As shown in FIG. 1C, the arrows represent the flow of electric charges 860, and the size of the arrow represents the magnitude of the flow. It can be seen that the electric charges congregate at the location closest to the interface of the first metal layer and the second metal layer. Accordingly, the electric flux of the first via 50 far form the second metal layer is smaller, and the electric flux of the first via 50′ closer to the second metal layer is larger. Therefore, the ITO layer 80 in the corresponding area will be damaged more easily and causes the display device to operate abnormally. Consequently, it is desirable to improve the conventional electrical connection structure.

### SUMMARY OF THE INVENTION

It is an object of the present invention to provide a conducting layer jump connection structure used in a circuit device for preventing a conducting layer from burning out.

It is another object of the present invention to provide a conducting layer jump connection structure used in a circuit device for increasing the path of the electric charge flow.

It is another object of the present invention to provide a circuit device having enhanced durability.

The conducting layer jump connection structure of the present invention includes a substrate, a first conducting layer, a first insulating layer, a second conducting layer, a second insulating layer, a jump connection layer, a first via, and a plurality of second vias. The first conducting layer covers the substrate. The first insulating layer covers the first conducting layer. The second conducting layer partially covers the first insulating layer. The second insulating layer covers the second conducting layer and the first insulating layer exposed by the second conducting layer. The jump connection layer covers the second insulating layer. On top of the jump connection layer is an electrical pad.

The first via is formed on the first conducting layer exposed by the second conducting layer and between two opposite second conducting layers, wherein the first via penetrates through both the second insulating layer and the first insulating layer. The second vias are formed on the second conducting layer and penetrate through the second insulating layer. The first conducting layer and the second conducting layer are connected to the jump connection layer by the conductive material filled in the first via and the second vias, respectively.

The first conducting layer may include metal. The second conducting layer may include metal. The jump connection layer may include indium tin oxide. The first via and the second vias are filled with a conductive material including indium tin oxide. The first insulating layer may include metal oxide. The second insulating layer may include metal oxide.

One second via is disposed on each of three adjacent sides of the first via, wherein the second conducting layer corresponding to the second vias forms a U shaped unit. A plurality of U shaped units are disposed side by side so that an opening of each U shaped unit faces a same direction.

The second conducting layer can be distributed as a fishbone configuration, wherein the second vias are disposed in a backbone area and splint bone areas of the fishbone configuration, and one first via is disposed between the splint bone areas of the fishbone configuration. The second conducting layer can be configured as a first column and a second column, wherein a plurality of first vias are disposed between the first column and the second column. The second conducting layer further respectively extends form the first column and the second column to form a plurality of U shaped units, wherein one first via is disposed in a central opening area of each U shaped unit.

The second conducting layer can be configured as a zigzag structure, wherein a plurality of first vias are disposed in recess areas of the zigzag structure. One first via and one adjacent second via are paired off so that the first via and the second vias are interlaced in pair with respect to a central axis of the zigzag structure. The zigzag structure includes a plurality of bodies and a plurality of connecting parts. The bodies are linearly disposed and spaced apart, and the connecting parts are respectively disposed between the adjacent bodies. The length of the body is larger than the width of the connecting part. A first end and a second end of one body are respectively electrically connected to a first end of a previous body and a second end of a next body by the connecting parts, wherein the second vias are located corresponding to the bodies, respectively.

### BRIEF DESCRIPTION OF THE DRAWINGS

FIG. 1A to FIG. 1C are schematic views of prior arts;

FIG. 2 is a schematic view of one embodiment of the present invention;

FIG. 3A is a schematic view of an embodiment of the present invention;

FIG. 3B is a top view of one embodiment of the present invention;

FIG. 4 is a top view of one embodiment of the present invention showing a second conducting layer distributed as two columns;

FIG. 5 is a top view of one embodiment of the present invention showing a second conducting layer formed as a U shaped unit;

FIG. 6 is a top view of one embodiment of the present invention showing a second conducting layer distributed as a plurality of U shaped units having the openings facing a same direction;

FIG. 7 is a top view of another embodiment of the present invention showing a second conducting layer distributed as two columns with U shaped units;

FIG. 8 is a top view of yet another embodiment of the present invention showing a second conducting layer in a fishbone configuration;

FIG. 9 is a top view of another embodiment of the present invention showing a second conducting layer encircling a T shaped area with a plurality of U shaped units in peripheral;

FIG. 10A is a top view of another embodiment of the present invention showing a second conducting layer distributed as a zigzag structure;

FIG. 10B is a schematic view of another embodiment of the present invention; and

FIG. 10C is a top view of another embodiment of the present invention showing a second conducting layer distributed as a zigzag structure;

### DETAILED DESCRIPTION OF THE PREFERRED EMBODIMENT

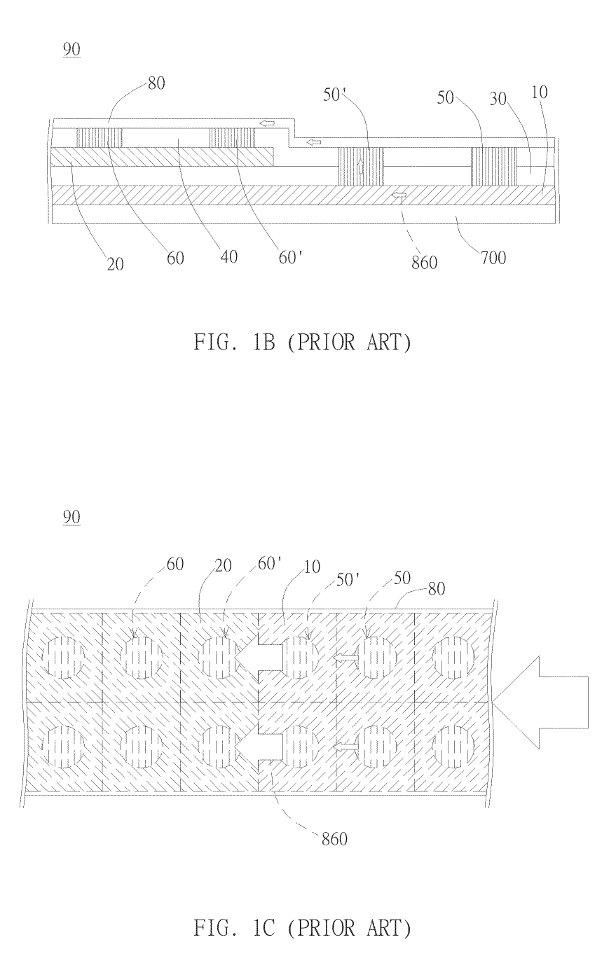

The present invention provides a conducting layer jump connection structure used in a circuit device. More particularly, in a preferred embodiment, the circuit device includes a circuit module of a liquid crystal display, wherein the circuit module includes the conducting layer jump connection structure. In other embodiments, however, the circuit device can be a circuit module of other electronic devices, and the display can be other types of displays instead of the liquid crystal display. As shown in FIG. 2, in a preferred embodiment, in the liquid crystal display 99, signals outside the display area 99a can be transmitted through a first conducting layer 100. However, for preventing interferences between the circuits, some signals can be directed into the display area 99a through the conducting layer jump connection structure 900 of the present invention and then transmitted through a second conducting layer 200. Since the interface between the first conducting layer 100 and the second conducting layer 200 is increased, the path for the electric charge flow is increased. Therefore, the overload of electric charges at the interface between the first conducting layer 100 and the second conducting layer 200 can be prevented.

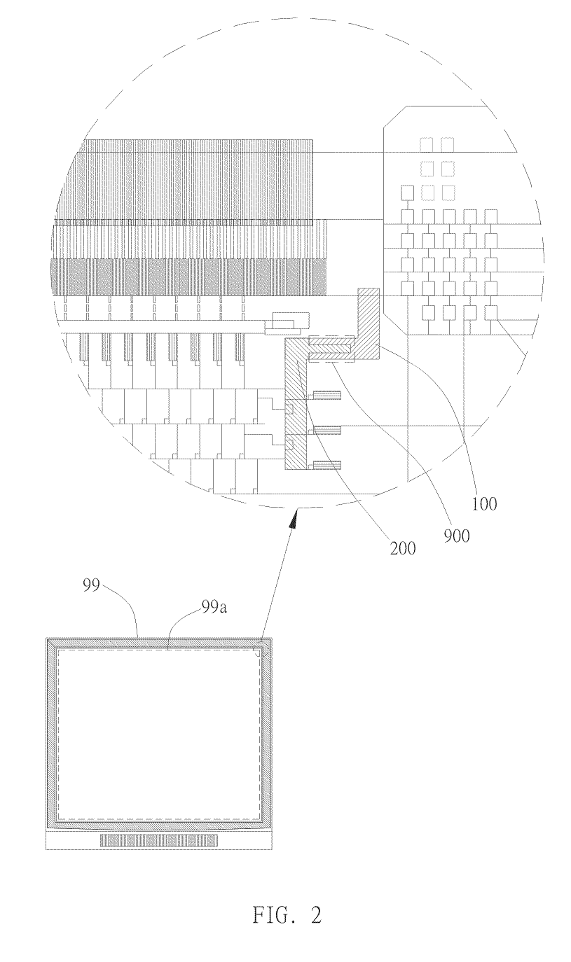

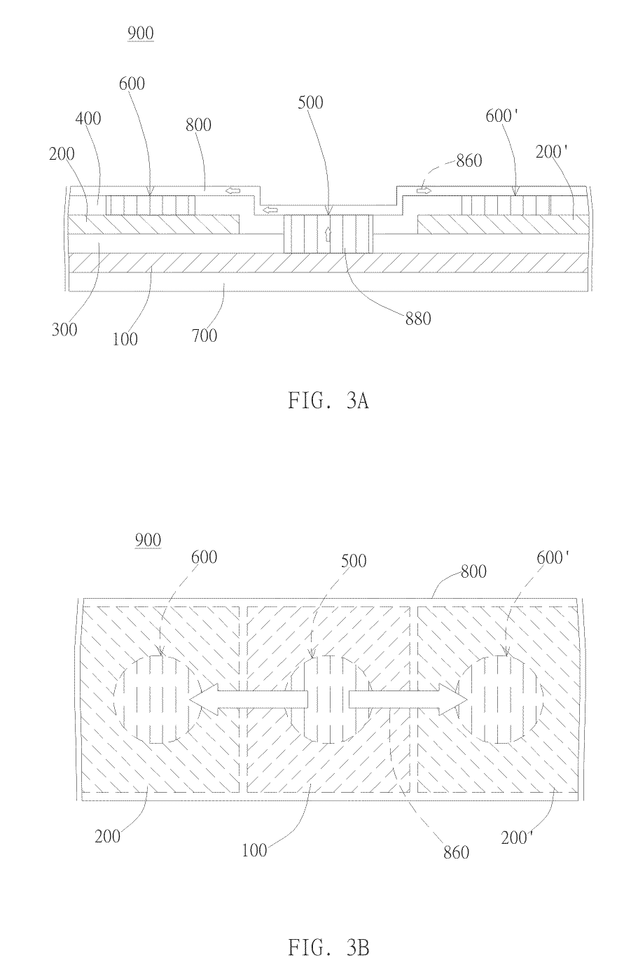

In a preferred embodiment shown in FIG. 3A, the conducting layer jump connection structure 900 of the present invention includes a substrate 700, a first conducting layer 100, a first insulating layer 300, a second conducting layer 200, a second insulating layer 400, a jump connection layer 800, a first via 500, and second vias 600 and 600′. The first conducting layer 100 covers the substrate 700. In a preferred embodiment, the first conducting layer 100 can be copper, aluminum, molybdenum, titanium, a laminated combination thereof, or an alloy thereof with other conductive materials. In other embodiments, however, the first conducting layer 100 can be a metal other than the above mentioned materials or a conductive nonmetallic material, such as graphite. The first conducting layer 100 can be formed by sputtering, evaporation, eletroplating, electroless plating, screen printing, or other methods.

As shown in FIG. 3A, the first insulating layer 300 covers the first conducting layer 100. In the preferred embodiment, the first insulating layer 300 can be aluminum oxide, silicon nitride, silicon oxide, or other insulating oxides. In other embodiments, the first insulating layer 300 can be a dielectric layer other than the above mentioned oxides or other transparent or opaque insulating materials such as ceramics and polymers. The first insulating layer 300 can be formed by chemical vapor deposition, sputtering, evaporation, eletroplating, electroless plating, screen printing, or other methods. The second conducting layer 200 partially covers the first insulating layer 300. In other words, the first insulating layer 300 is partially exposed by the second conducting layer 200. In a preferred embodiment, the second conducting layer 200 can be copper, aluminum, molybdenum, titanium, a laminated combination thereof, or an alloy thereof with other conductive materials. In other embodiments, however, the second conducting layer 200 can be a metal other than the above mentioned materials or a conductive nonmetallic material, such as graphite. The second conducting layer 200 can be formed by sputtering, evaporation, eletroplating, electroless plating, screen printing, or other methods.

As shown in FIG. 3A, the second insulating layer 400 covers the second conducting layer 200 and the first insulating layer 300 exposed by the second conducting layer 200. In the preferred embodiment, the second insulating layer 400 can be aluminum oxide, silicon nitride, silicon oxide, or other insulating oxides or nitrides. In other embodiments, the second insulating layer 400 can be a dielectric layer other than the above mentioned oxides or other transparent or opaque insulating materials, such as ceramics and polymers. The second insulating layer 400 can be formed by chemical vapor deposition, sputtering, evaporation, eletroplating, electroless plating, screen printing, or other methods.

As shown in FIG. 3A, the jump connection layer 800 covers the second insulating layer 400. The first via 500 is formed on the first conducting layer 100 and between the second conducting layers 200. For example, the first via 500 is interposed between two opposite second conducting layers 200 and 200′. The first via 500 penetrates through both the second insulating layer 400 and the first insulating layer 300. In other words, the first conducting layer 100 is electrically coupled to the jump connection layer 800 by the conductive material filled in the first via 500 exposed between the two opposite second conducting layers 200 and 200′. The second vias 600 and 600′ are formed on the second conducting layer 200. For example, the second vias 600 and 600′ are respectively formed on the second conducting layers 200 and 200′ and penetrate through the second insulating layer 400. In other words, the second conducting layer 200 is electrically coupled to the jump connection layer 800 through the second via 600, and the second conducting layer 200′ is electrically coupled to the jump connection layer 800 through the second via 600′. The cross section of the first via 500 and the second via 600 can respectively be a circle, a rectangle, or a polygon.

The jump connection layer 800 is preferably an indium tin oxide layer or other conducting materials. The electric resistance of the jump connection layer 800 is larger than the electric resistances of the first conducting layer 100 and the second conducting layer 200. The jump connection layer 800 is preferably transparent when being disposed in a display area and can be formed in a same manufacturing step with a pixel electrode. In other embodiments, however, the jump connection layer 800 can be selected from the above mentioned metals or conductive nonmetal materials. The jump connection layer 800 can be formed by spin coating, plate coating, screen printing, or other methods. The first conducting via 500 and the second via 600 are filled with a conductive material 880, such as indium tin oxide, respectively. In other embodiments, however, the conductive material 880 can be a metal or a conductive nonmetal material. The first conducting layer 100 and the second conducting layer 200 are respectively electrically coupled to the conductive material 880 filled in the first via 500 and the second via 600 and electrically coupled to the jump connection layer 800. More particularly, two ends of the conductive material 880 in the first via 500 are electrically coupled with the first conducting layer 100 and the jump connection layer 800, respectively. Two ends of the conductive material 880 in the second vias 600 and 600′ are electrically coupled with the second conducting layers 200 and 200′ and the jump connection layer 800, respectively. For example, the electric charges can flow from the first conducting layer 100 to the jump connection layer 800 through the conductive material 880 in the first via 500, and then flow from the jump connection layer 800 to the second conducting layer 200 through the conductive material 880 in the second vias 600 and 600′. In other words, the path of the electric charge flow is increased by making the two ends of the conductive material 880 in the two seconds via 600 and 600′ respectively electrically coupled to the second conducting layers 200 and 200′ to prevent the jump connection layer 800 from burning out because of the electric charge overload. Hence, the durability of the circuit device is improved.

As shown in FIG. 3A and FIG. 3B, the second vias 600 and 600′ electrically coupled to the second conducting layers 200 and 200′ and filled with the conductive material 880 are respectively disposed on two sides of the first via 500, which is electrically coupled to the first conducting layer 100 and filled with the conductive material 880. Therefore, the current density is dispersed since the electric charge flow 860 can flow from the first via 500 to the two second vias 600 and 600′ disposed on two sides of the first via 500 through the jump connection layer 800.

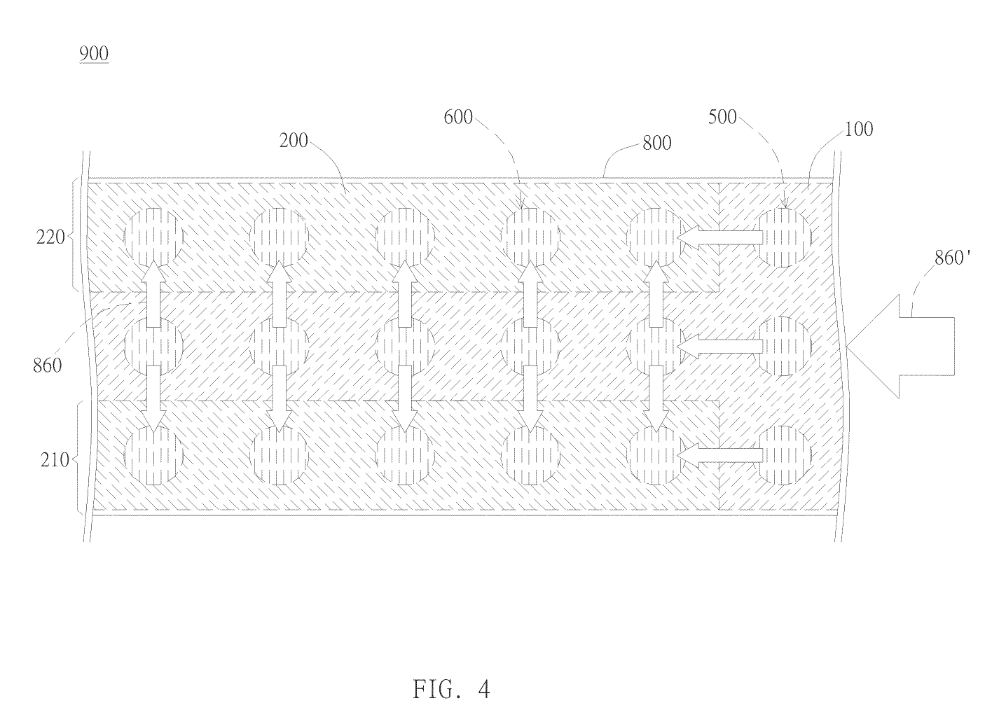

The configuration of the conducting layer jump connection structure will now be described in greater detail. In preferred embodiments, the conducting layer jump connection structure 900 of the present invention can be combined with same or different configurations. As shown in FIG. 4, multiple conducting layer jump connection structures 900 shown in FIG. 3B are disposed side by side so that the second conducting layer 200 is distributed as a first column 210 and a second column 220. A plurality of first vias 500 are disposed between the first column 210 and the second column 220, and a plurality of second vias 600 are disposed in the first column 210 and the second column 220. The electric charge flow 860′ can flow from the right side to the first vias 500 disposed between the first column 210 and the second column 220 and then flow to the adjacent second vias 600 disposed on two sides of the first vias 500 through the jump connection layer 800. In other words, the path of the electric charge flow is increased to prevent the jump connection layer 800 from burning out because of the electric charge overload. Hence, the durability of the circuit device is improved.

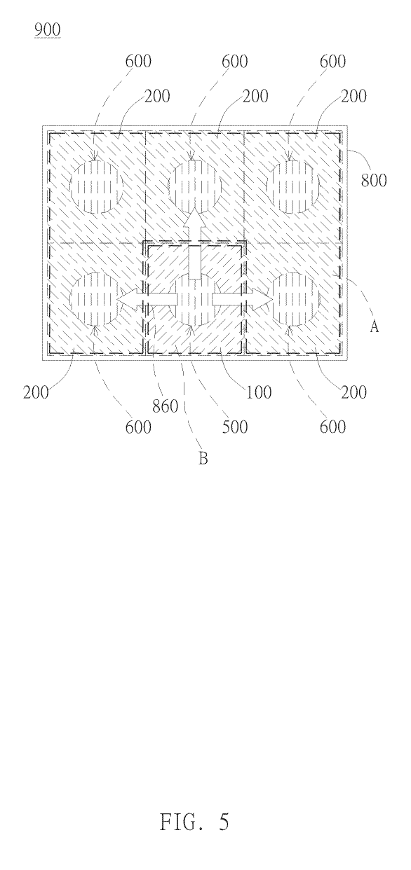

In another embodiment, as shown in FIG. 5, one second via 600 is disposed on each of three adjacent sides of the first via 500 so as to form a U shaped unit. In other words, the second conducting layer 200 corresponding to the second vias 600 is configured to form the U shaped unit, wherein the first conducting layer 100 is partially exposed in the central opening area of the U shaped unit. In this embodiment, the electricity charge flow 860 can flows from the first via 500 to the second vias 600 on the three adjacent sides through the jump connection layer 800.

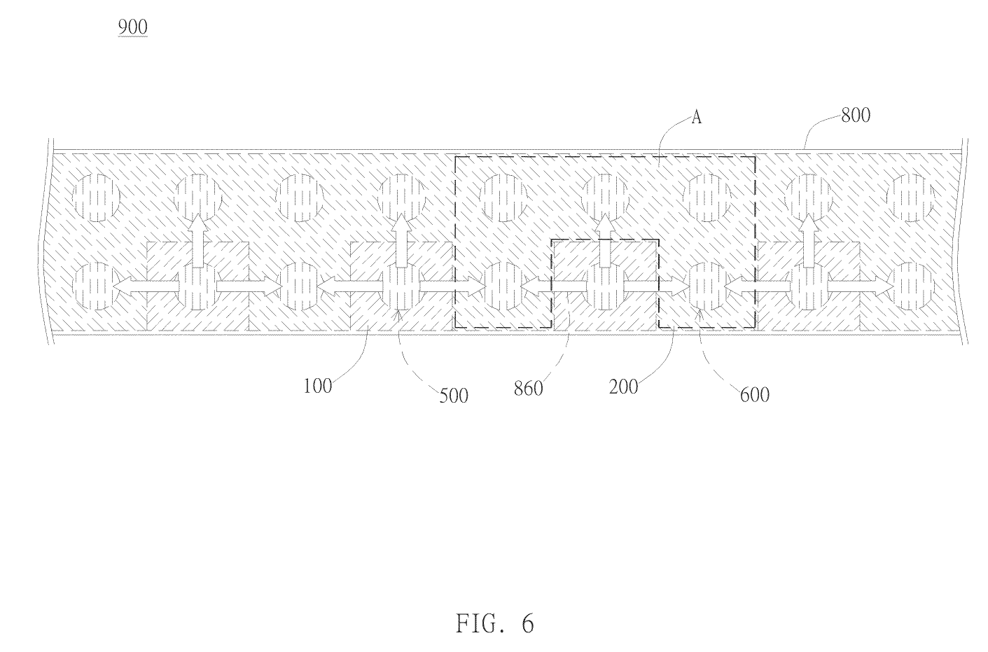

The configuration of the second conducting layer 200 shown in FIG. 5, which includes three second vias 600 disposed around three adjacent sides of the first via 500 to form the U shaped unit A with the first via 500 disposed in the central opening area B of the U shaped unit A, can be modified in other embodiments. For example, as shown in FIG. 6, a plurality of U shaped units A can be disposed side by side so that the opening of each U shaped unit A faces a same direction.

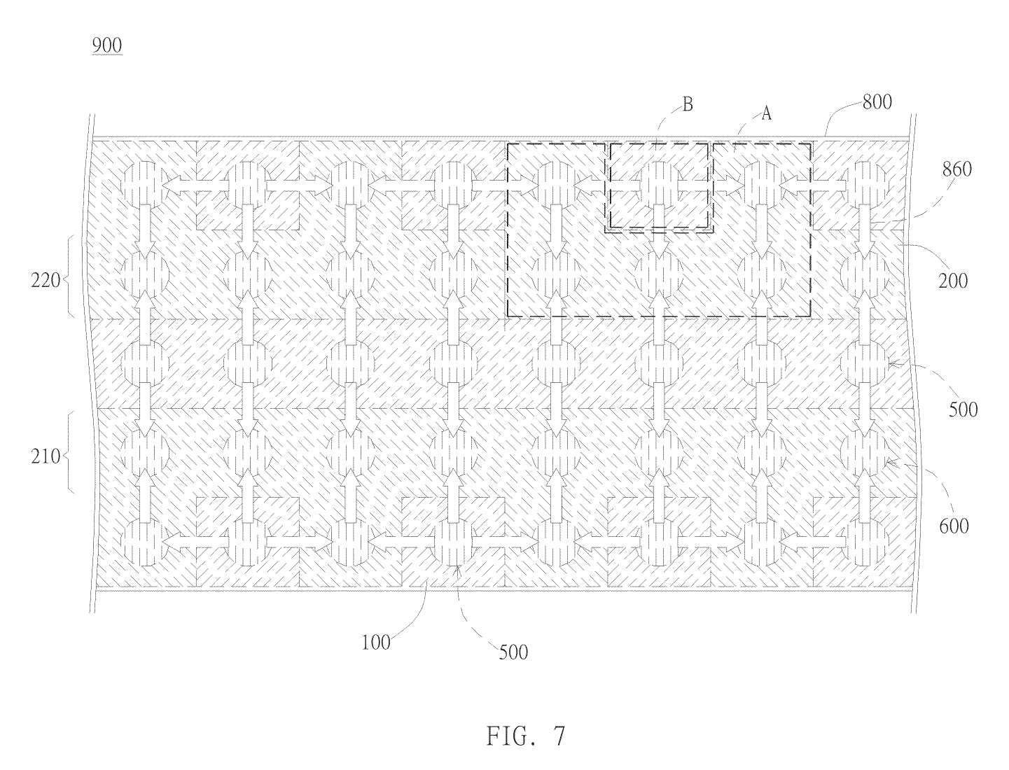

In another embodiment, the dual column configuration shown in FIG. 4 and the configuration of the U shaped units shown in FIG. 6 can be combined to form a modified configuration shown in FIG. 7. As shown in FIG. 7, the second conducting layer 200 further respectively extends form the first column 210 and the second column 220 to form a plurality of U shaped units A, wherein one first via 500 is disposed in the central opening area B of each U shaped unit A.

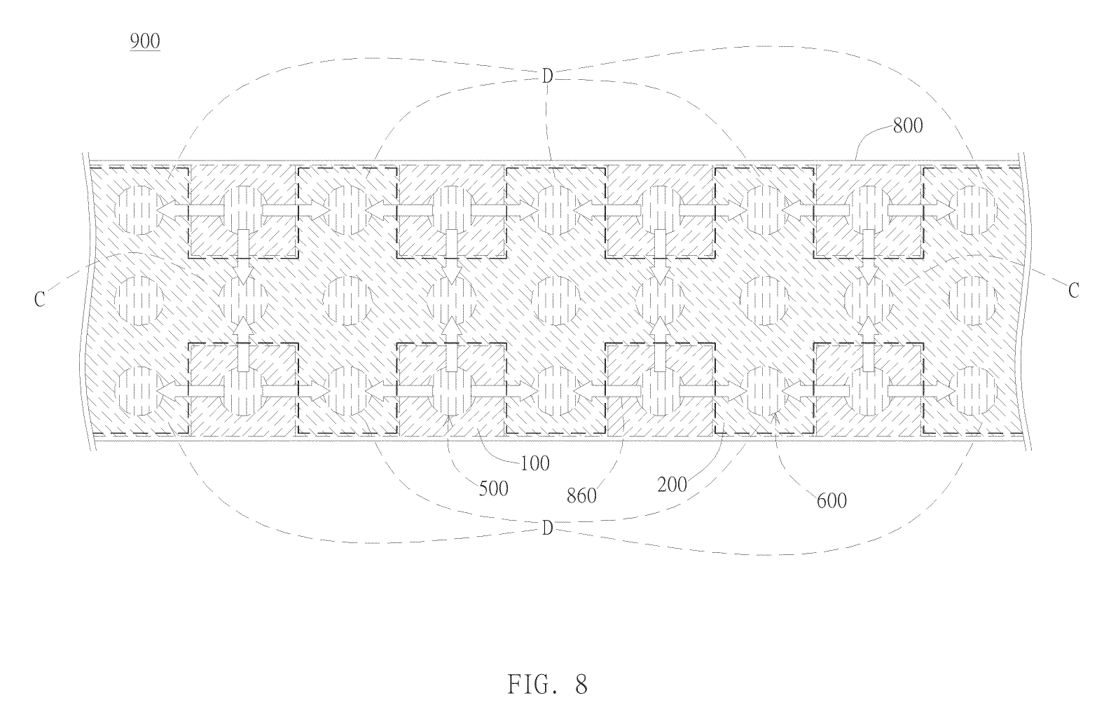

In another embodiment shown in FIG. 8, the second conducting layer 200 can be distributed as a fishbone configuration, wherein the second vias 600 are distributed in the backbone area C and the splint bone areas D of the fishbone configuration while the first vias 500 are disposed in the areas between the splint bones areas D. In other words, in this embodiment, the first vias 500 are bone area D and a part of the backbone area C between the two splint bone areas D of the fishbone configuration.

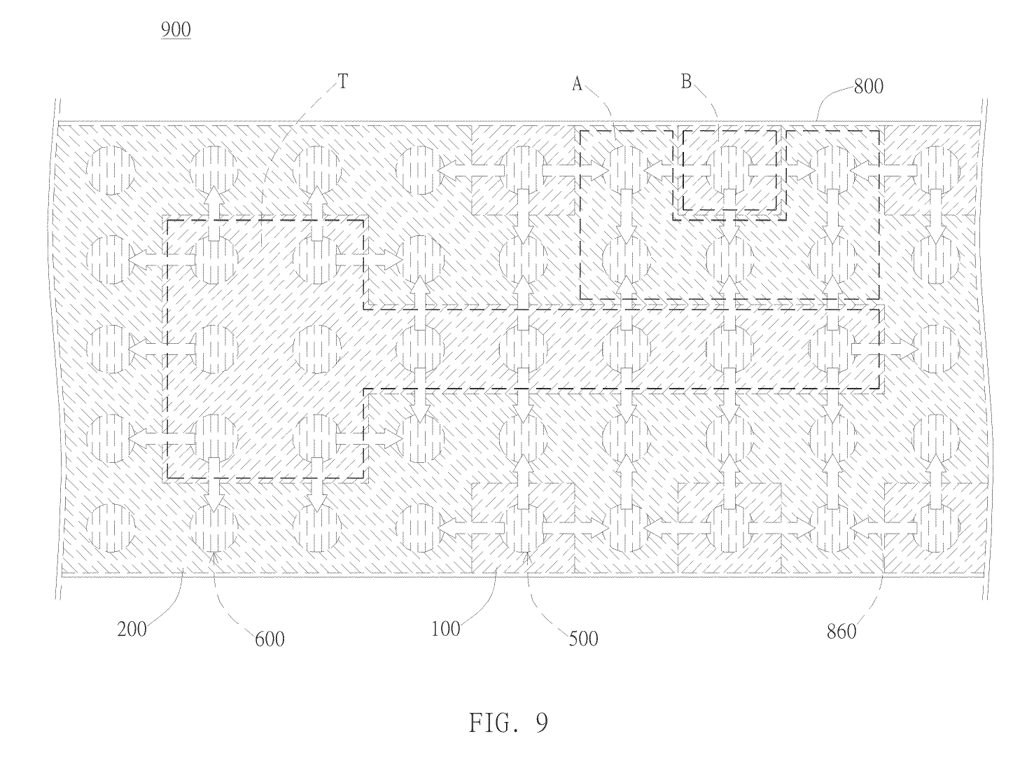

In another embodiment shown in FIG. 9, the second conducting layer 200 is further configured to encircle a T shaped area T with a plurality of U shaped units in peripheral. The first vias 500 are disposed in the T-shaped area T and the central opening areas of the U shaped units. In this embodiment, the U shaped units A, which have three second vias 600 disposed around three adjacent sides of the first via 500, are disposed side by side on two sides of the T shaped area T with the openings of the U shaped units A facing outward. That is, the openings of the U shaped units on two sides of the T shaped area face opposite directions. Furthermore, the second conducting layer 200 around the head portion of the T shaped area T is configured to have a plurality of second vias 600 disposed around the first vias 500 in the head portion of the T shaped area T.

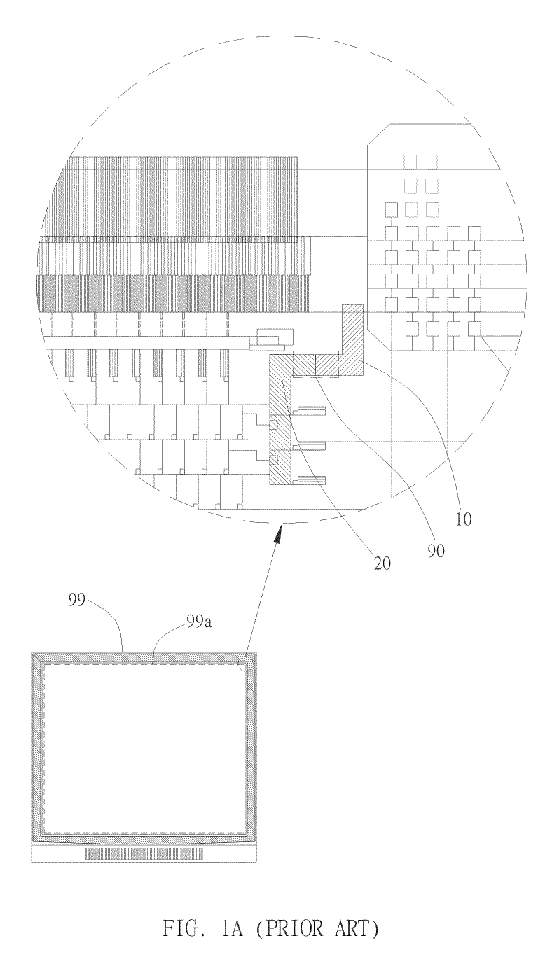

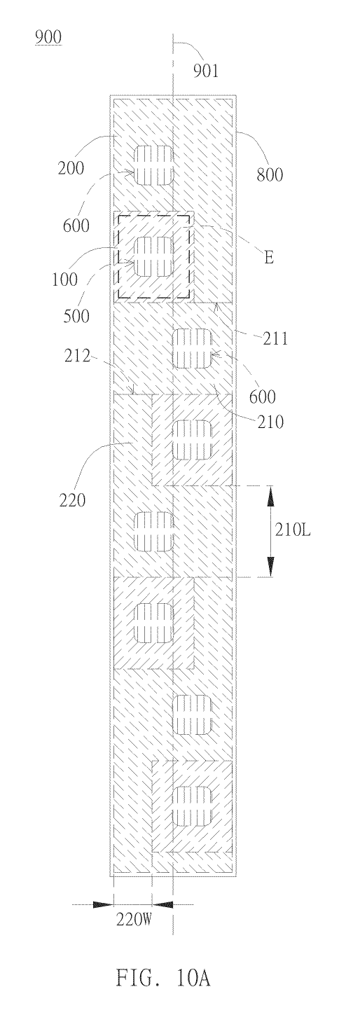

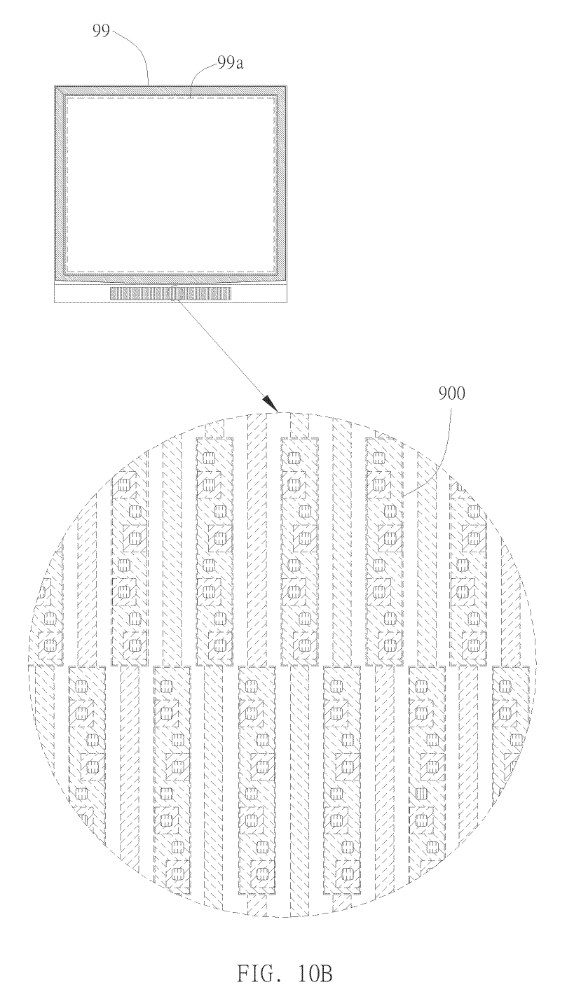

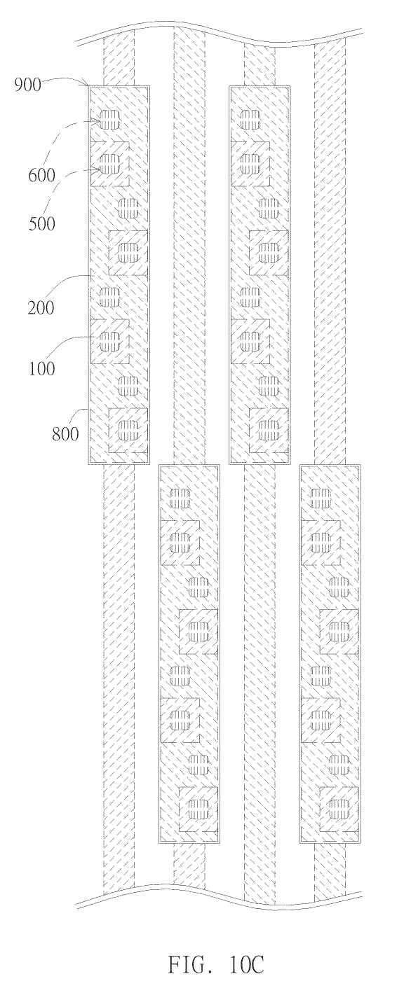

In another embodiment shown in FIG. 1A, the second conducting layer 200 is configured as a zigzag structure, wherein the first vias 500 are disposed in the recess areas E of the zigzag structure. The first vias 500 and the adjacent second vias 600 are paired off and interlaced in pair with respect to the central axis 901 of the zigzag structure. More particularly, as shown in FIG. 10A, the zigzag structure includes a plurality of bodies 210 and a plurality of connecting parts 220. The length 210L of the body 210 is larger than the width 220W of the connecting part 220. The plurality of bodies are linearly disposed and spaced apart, and the plurality of connecting parts 220 are disposed between the adjacent bodies 210. A first end 211 and a second end 212 of one body 210 are respectively electrically connected to a first end 211 of a previous body 210 and a second end 212 of a next body 210 by the connecting parts 220. The second vias are located corresponding to the bodies, respectively. In such a configuration, the width of the conducting layer jump connection structure 900 can be further decreased.

The above mentioned embodiment can be applied to an area with denser circuits, such as a pad area. As shown in FIG. 10B, the conducting layer jump connection structure 900 can be applied in a panel to connect with the pad areas of integrated circuits (not shown). The number of the conducting layer jump connection structure per unit area can be increased depending on the needs. The signals output from the integrated circuits can come from different sources to enter the display area 99a of the panel. Therefore, signals from different sources have to be respectively transmitted by the first conducting layer or the second conducting layer. Using the conducting layer jump connection structure 900 of the present invention can transmit the signal from the first conducting layer to the second conducting layer or from the second conducting layer to the first conducting layer. As shown in FIG. 10C, two ends of each conducting layer jump connection structure 900 can be respectively or simultaneously connected to the input or output circuits of the first conducting layer 100 and the second conducting layer 200. The jump connection layer 800 on top of the conducting layer jump connection structure 900 forms an electrical pad for connecting with a connecting block and receiving the signal output by the connecting block, wherein the integrated circuits output signals through the connecting block.

The present invention can be applied to not only the conductive layer jump connection structure in the circuits outside the display area of the panel in the embodiments, but also the conductive connection structure in the display area. Therefore, the path of the electric charge flow is increased to prevent the jump connection layer from burning out because of the electric charge overload. Hence, the durability of the circuit device is improved.

Also, with regard to different display modes and laminated designs, the above mentioned display panel can be used as a transmissive display panel, a semi-transmissive display panel, a reflective display panel, a color filter on array display panel, an array on color filter display panel, a vertical alignment (VA) display panel, an in-plane switching (IPS) display panel, a multi-domain vertical alignment (MVA) display panel, a twisted nematic (TN) display panel, a super TN (STN) display panel, a patterned vertical alignment (PVA) display panel, a super PVA (S-PVA) display panel, an advanced super view (ASV) display panel, a fringe filed switching (FFS) display panel, a continuous pinwheel alignment (CPA) display panel, an axially symmetric aligned micro-cell mode (ASM) display panel, an optically compensated bend (OCB) display panel, a super IPS (S-IPS) display panel, an advanced super IPS (AS-IPS) display panel, an ultra FFS (UFFS) display panel, a polymer stabilized alignment display panel, a dual-view display panel, a triple-view display panel, a three-dimensional display panel, a touch panel, an organic light emitting diode display panel, a low temperature poly-silicon (LTPS) display panel, a plasma display panel (PDP), a flexible display panel, or other display panels or the combination thereof.

Although the preferred embodiments of the present invention have been described herein, the above description is merely illustrative. Further modification of the invention herein disclosed will occur to those skilled in the respective arts and all such modifications are deemed to be within the scope of the invention as defined by the appended claims.

What is claimed is:

1. A conducting layer jump connection structure, comprising:
a substrate;
a first conducting layer covering the substrate;
a first insulating layer covering the first conducting layer;
a second conducting layer partially covering the first insulating layer;
a second insulating layer covering the second conducting layer and the first insulating layer exposed by the second conducting layer;
a jump connection layer covering the second insulating layer;
a first via formed on the first conducting layer exposed by the second conducting layer and between two opposite second conducting portions of the second conducting layers, wherein the first via penetrates through both the second insulating layer and the first insulating layer; and
a plurality of second vias formed on the second conducting layer and penetrating through the second insulating layer;
wherein the first conducting layer and the second conducting layer are electrically connected to the jump connection layer by the conductive material filled in the first via and the second vias, respectively.

2. The conducting layer jump connection structure of claim 1, wherein the first conducting layer includes metal.

3. The conducting layer jump connection structure of claim 1, wherein the second conducting layer includes metal.

4. The conducting layer jump connection structure of claim 1, wherein the jump connection layer includes indium tin oxide.

5. The conducting layer jump connection structure of claim 1, wherein the first via and the second vias are filled with a conductive material including indium tin oxide.

6. The conducting layer jump connection structure of claim 1, wherein the first insulating layer includes metal oxide.

7. The conducting layer jump connection structure of claim 1, wherein one second via is disposed on each of three adjacent sides of the first via so that the second conducting layer corresponding to the second vias forms a U shaped unit.

8. The conducting layer jump connection structure of claim 7, wherein a plurality of U shaped units are disposed side by side so that an opening of each U shaped unit faces a same direction.

9. The conducting layer jump connection structure of claim 1, wherein the second conducting layer corresponding to the first via and the second vias is configured as a U shaped unit, wherein a plurality of U shaped units are disposed so that openings of adjacent U shaped units face opposite directions.

10. The conducting layer jump connection structure of claim 1, wherein the second conducting layer is distributed as a fishbone configuration, the second vias are disposed in a backbone area and splint bone areas of the fishbone configuration, and the first via is disposed between the splint bone areas of the fishbone configuration.

11. The conducting layer jump connection structure of claim 1, wherein the second conducting layer is configured as a first column and a second column, a plurality of first vias are disposed between the first column and the second column.

12. The conducting layer jump connection structure of claim 11, wherein the second conducting layer further respectively extends form the first column and the second column to form a plurality of U shaped units, wherein one first via is disposed in a central opening area of the U shaped unit.

13. The conducting layer jump connection structure of claim 1, wherein the second conducting layer is configured as a zigzag structure, wherein a plurality of first vias are disposed in recess areas of the zigzag structure.

14. The conducting layer jump connection structure of claim 13, wherein the first via and adjacent second via are paired off so that the first vias and the second vias are interlaced in pair with respect to a central axis of the zigzag structure.

15. The conducting layer jump connection structure of claim 13, wherein the zigzag structure includes a plurality of bodies and a plurality of connecting parts, the bodies are linearly disposed and spaced apart, the connecting parts are disposed between the adjacent bodies, a first end and a second end of one body are respectively electrically connected to a first end of a previous body and a second end of a next body by the connecting parts, wherein the second vias are located corresponding to the bodies.

16. The conducting layer jump connection structure of claim 15, the length of the body is larger than the width of the connecting part.

17. The conducting layer jump connection structure of claim 13, wherein on top of the jump connection layer is an electrical pad.

18. A circuit device, comprising:
a substrate;
a first conducting layer covering the substrate;
a first insulating layer covering the first conducting layer;
a second conducting layer partially covering the first insulating layer;
a second insulating layer covering the second conducting layer and the first insulating layer exposed by the second conducting layer;
a jump connection layer covering the second insulating layer;
a plurality of first vias formed on the first conducting layer exposed by the second conducting layer, wherein the first via penetrates through both the second insulating layer and the first insulating layer; and
a plurality of second vias formed on the second conducting layer and penetrating through the second insulating layer;
wherein the first conducting layer and the second conducting layer are connected to the jump connection layer by the conductive material filled in the first via and the second vias, respectively.

19. The circuit device of claim 18, wherein the first conducting layer includes metal.

20. The circuit device of claim 18, wherein the second conducting layer includes metal.

21. The circuit device of claim 18, wherein the jump connection layer includes indium tin oxide.

22. The circuit device of claim 18, wherein the first via and the second vias are filled with a conductive material including indium tin oxide.

23. The circuit device of claim 18, wherein the second insulating layer includes metal oxide.

24. The circuit device of claim 18, wherein one second via is disposed on each of three adjacent sides of the first via so that the second conducting layer corresponding to the second vias forms a U shaped unit.

25. The circuit device of claim 24, wherein a plurality of U shaped units are disposed side by side so that an opening of each U shaped unit faces a same direction.

26. The circuit device of claim 24, wherein a plurality of U shaped units are disposed side by side so that openings of adjacent U shaped units face opposite directions.

27. The circuit device of claim 18, wherein the second conducting layer is distributed as a fishbone configuration, the second vias are disposed in a backbone area and splint bone areas of the fishbone configuration, and the first via is disposed between the splint bone areas of the fishbone configuration.

28. The circuit device of claim 18, wherein the second conducting layer is configured as a first column and a second column, a plurality of first vias are disposed between the first column and the second column.

29. The circuit device of claim 28, wherein the second conducting layer further respectively extends form the first column and the second column to form a plurality of U shaped units, wherein one first via is disposed in a central opening area of the U shaped unit.

30. The circuit device of claim 18, wherein the second conducting layer is configured as a zigzag structure, wherein a plurality of first vias are disposed in recess areas of the zigzag structure.

31. The circuit device of claim 30, wherein the first via and adjacent second via are paired off so that the first vias and the second vias are interlaced in pair with respect to a central axis of the zigzag structure.

32. The circuit device of claim 30, wherein the zigzag structure includes a plurality of bodies and a plurality of connecting parts, the bodies are linearly disposed and spaced apart, the connecting parts are disposed between the adjacent bodies, a first end and a second end of one body are respectively electrically connected to a first end of a previous body and a second end of a next body by the connecting parts, wherein the second vias are located corresponding to the bodies.

33. The circuit device of claim 32, the length of the body is larger than the width of the connecting part.

34. The circuit device of claim 30, wherein on top of the jump connection layer is an electrical pad.
